(19) United States
(12) Patent Application Publication
(10) Pub. No.: US 2014/0284080 A1
(43) Pub. Date: Sep. 25, 2014

(54) PRINTED CIRCUIT BOARD AND METHOD OF MOUNTING INTEGRATED CIRCUIT PACKAGING COMPONENT ON THE SAME

(71) Applicants: Tech-Front (shanghai) Computer Co. Ltd., Songjiang EPZ Shanghai (CN); Quanta Computer Inc., Taoyuan Shien (TW)

(72) Inventors: Jing ZHANG, Songjiang EPZ Shanghai (CN); Jin-Chang WU, New Taipei City 220 (TW); Xiao-Feng XIE, Songjiang EPZ Shanghai (CN)

(73) Assignees: Tech-Front (shanghai) Computer Co. Ltd., Songjiang EPZ Shanghai (CN); Quanta Computer Inc., Taoyuan Shien (TW)

(21) Appl. No.: 14/086,856

(22) Filed: Nov. 21, 2013

(30) Foreign Application Priority Data
Mar. 21, 2013 (CN) 201310091289.8

(51) Int. Cl. H05K 1/11; H05K 13/04

(52) U.S. Cl. CPC H05K 1/111; H05K 13/0465
USPC 174/250; 228/180.22

(57) ABSTRACT

A printed circuit board and a method of mounting an integrated circuit packaging component on the same are provided. The printed circuit board includes a substrate and a plurality of conductive contacts arranged on a surface of the substrate. Each of the conductive contacts has a soldering material layer formed on a top surface thereof, and a concave portion formed on the soldering material layer. Each of the concave portions is aligned with a vertex of the ball-conducting joint for allowing a vertex of the ball conducting joint to extend into the concave portion.

### CROSS-REFERENCE TO RELATED APPLICATIONS

This application claims priority to China Application Serial Number 201310091289.8, filed Mar. 21, 2013, which are herein incorporated by reference.

### FIELD OF THE INVENTION

The disclosure relates to a printed circuit board. More particularly, the disclosure relates to a printed circuit board capable of effectively enhancing a soldering effect.

### BACKGROUND

In a conventional integrated circuit packaging component, a ball grid array (BGA) is welded on a printed circuit board. A plurality of tiny solder joints of the integrated circuit packaging component are respectively bonded on a solder material layers of the printed circuit board, so as to provide electrical and physical connections between the integrated circuit packaging component and the printed circuit board.

However, some of the solder joints of the integrated circuit packaging component often fail to be completely melted with the corresponding solder material layer of the printed circuit boards one piece during the welding process, thus resulting in the failure of the electrical connections between the integrated circuit packaging component and the printed circuit board , or at least degrading the electrical conductivity performance between the integrated circuit packaging component and the printed circuit board might.

In view of this, how to develop an integrated circuit packaging component capable of improving the aforementioned disadvantages and inconveniences is an important issue to those in this industry.

### SUMMARY

The present disclosure is to provide a printed circuit board and a method of mounting an integrated circuit packaging component on the same. Because of concave portions respectively formed on soldering material layers of the printed circuit board, when the integrated circuit packaging component is stacked onto the printed circuit board, vertexes of ball-conducting joints of the integrated circuit packaging component can be sunk and received in the concave portions, so that a maximum distance defined between the printed circuit board and a down-most vertex of the ball-conducting joints can be effectively reduced, and an effective contact area that the ball-conducting joint contacts the soldering material layer can be increased.

According to one embodiment of the present disclosure, a printed circuit board is provided. An integrated circuit packaging component with ball-conducting joints can be mounted on the printed circuit board. The printed circuit board includes a substrate and a plurality of conductive contacts. The conductive contacts are arranged on a surface of the substrate. Each of the conductive contacts has a soldering material layer formed on a top surface thereof. Each of the soldering material layers has a concave portion formed thereon, and each of the concave portions can be arranged to be aligned with a vertex of one of the ball-conducting joints for receiving the vertex of the ball-conducting joint.

According to another embodiment of the present disclosure, a method of mounting an integrated circuit packaging component on a printed circuit board. The method includes steps: (a) a printed circuit board having a plurality of conductive contacts and an integrated circuit packaging component having a plurality of ball-conducting joints are provided; (b) soldering material layers are respectively formed on top surfaces of the conductive contacts, and each of the soldering material layers is formed with a concave portion thereon; (c) the integrated circuit packaging component is stacked onto the printed circuit board, and the concave portions of the soldering material layers are respectively aligned with vertexes of the ball-conducting joints, such that the vertexes of at least some of the ball-conducting joints are respectively received in the corresponding concave portions; and (d) the integrated circuit packaging component and the printed circuit board are heated, such that each of the soldering material layers and the corresponding ball-conducting joint received in the concave portion are completely melted as one piece.

As what has been disclosed above, with the printed circuit board and the method of mounting an integrated circuit packaging component on the same provided by the present disclosure, the quantity of the ball-conducting joints which fail to be completely melted with the corresponding solder material layer as one piece can be reduced, and the possibility that all of the ball-conducting joints completely melted with the corresponding solder material layer as one piece during the welding process can be increased.

### BRIEF DESCRIPTION OF THE DRAWINGS

The present disclosure will be apparent to those skilled in the art by reading the following detailed description of a preferred embodiment thereof, with reference to the attached drawings, in which:

FIG. 1 is a schematic view showing an integrated circuit packaging component mounted on a printed circuit board;

FIG. 2 is a schematic view showing a ball-conducting joint in a welding process failing to be completely melted with a solder material layer as one piece;

FIG. 3 is a side view of a printed circuit board according to one embodiment of the present disclosure;

FIG. 4A is a partial top view showing a zone M of FIG. 3 according to one embodiment of the present disclosure;

FIG. 4B is a partial top view showing the zone M of FIG. 3 according to another embodiment of the present disclosure;

FIG. 5 is a flow chart showing a method of mounting an integrated circuit packaging component on the printed circuit board according to one embodiment of the present disclosure;

FIG. 6 is a schematic operational view showing the integrated circuit packaging component mounted on the printed circuit board according to one embodiment of the present disclosure;

FIGS. 7A and 7B are schematic operational schematic views showing step (502) of FIG. 5 according to one embodiment of the present disclosure;

FIG. 7C is a partial top view showing a solder material layer formed on the printed circuit board according to the embodiment of FIGS. 7A and 7B; and

FIG. 8 is a schematic operational schematic view showing step (502) of FIG. 5 according to another embodiment of the present disclosure.

### DETAILED DESCRIPTION

The spirit of the disclosure will be described clearly through the drawings and the detailed description as follows. Any of those of ordinary skills in the art can make modifications and variations from the technology taught in the disclosure after understanding the embodiments of the disclosure, without departing from the sprite and scope of the disclosure.

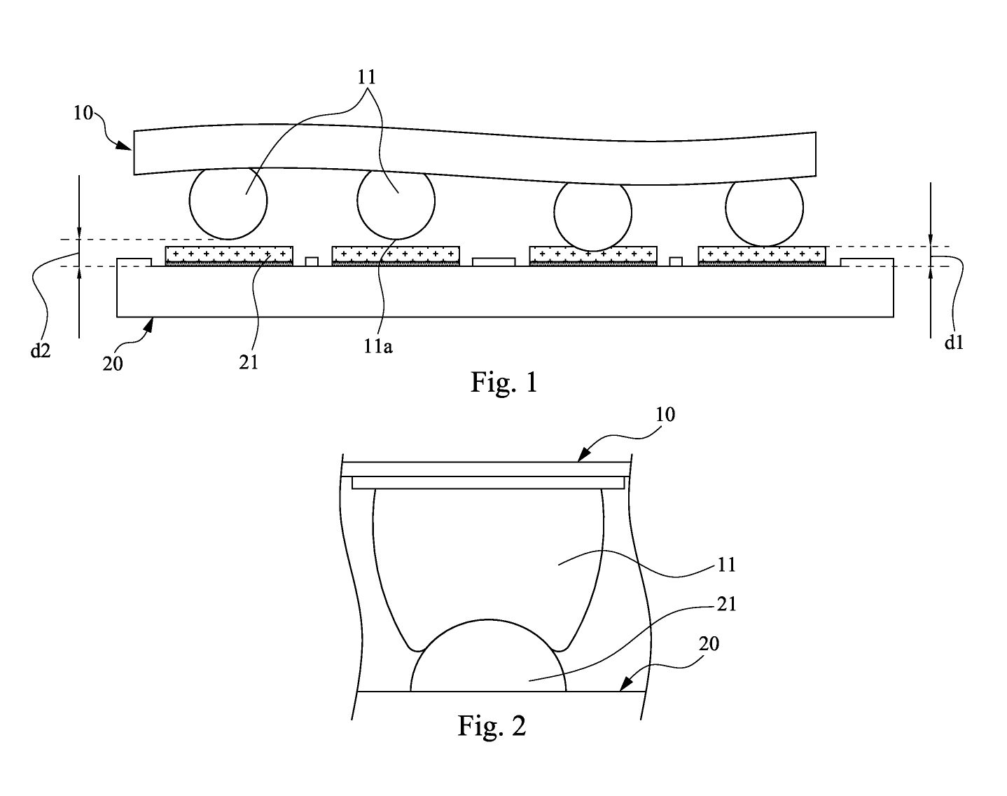

Reference is now made to FIG. 1 and FIG. 2, in which FIG. 1 is a schematic view showing an integrated circuit packaging component 10 being mounted on a printed circuit board 20, and FIG. 2 is a schematic view showing a ball-conducting joint 11 in a welding process failing to be completely melted with a solder material layer 21 as one piece.

As shown in FIG. 1 and FIG. 2, when the integrated circuit packaging component 10 is stacked on the printed circuit board 20, the ball-conducting joints 11 are correspondingly aligned with the solder material layers 21 one by one. Since the integrated circuit packaging component 10 is increasingly thin in thickness, when both of the integrated circuit packaging component 10 and the printed circuit board 20 are sent to a welding process, due to a high temperature environment, a segment of the integrated circuit packaging component 10 will be warped in shape, so that the distances respectively defined between the vertexes 11a of the different ball-conducting joints 11 and the printed circuit board 20 are apparently different (e.g., distance d1, d2), thus causing some of the ball-conducting joints 11 (the left two ball-conducting joints 11 in FIG. 1) to fail to physically contact the corresponding solder material layers 21. Therefore, each of these ball-conducting joints 11 cannot be completely melted with the corresponding solder material layer 21 as one piece during the welding process (FIG. 2).

In view of this, the present invention forms a plurality of concave portions on all of the soldering material layers of the printed circuit board. Because of the concave portions on the soldering material layers of the printed circuit board, when the integrated circuit packaging component is stacked onto the printed circuit board, vertexes of ball-conducting joints of the integrated circuit packaging component can be sunk and received in the concave portions, so that a maximum distance defined between the printed circuit board and the down-most vertex of the ball-conducting joint can be effectively reduced, thereby reducing the distances defined between the printed circuit board and parts of ball-conducting joints on the warpage segment of the integrated circuit packaging component during the welding process, so as to decrease the possibility that the parts of ball-conducting joints on the warpage segment of the integrated circuit packaging component failing to be completely melted with the corresponding solder material layers as one piece during the welding process. Furthermore, since the concave portion of the soldering material layer is hollow, when the integrated circuit packaging component is stacked onto the printed circuit board, the down-most vertex of the ball-conducting joint can be closer to the inside of the concave portion of the soldering material layer, so as to increase the effective contact area that the ball-conducting joint contacts the soldering material layer.

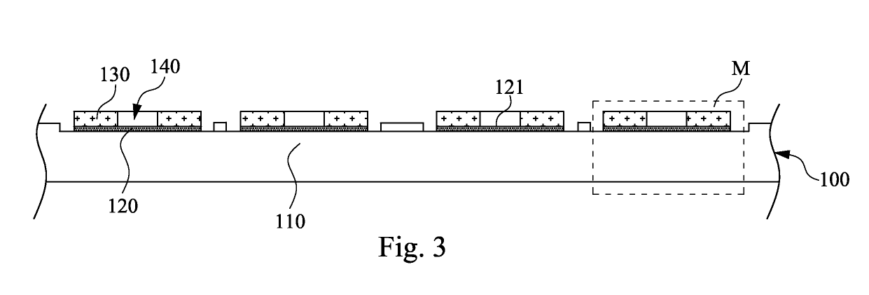

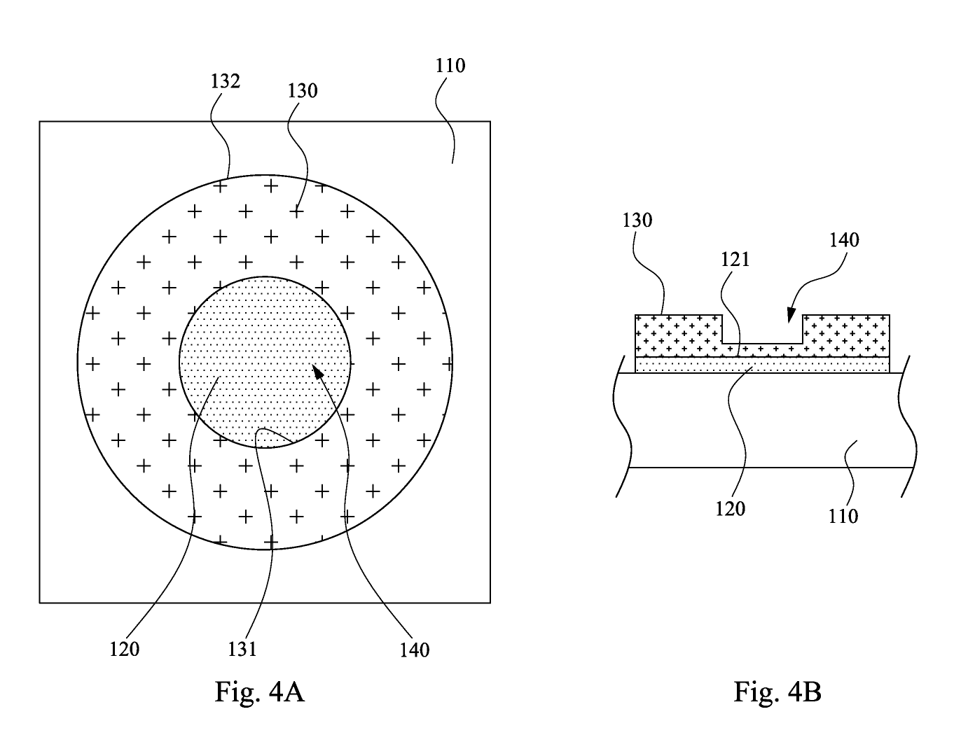

Reference is now made to FIG. 3 and FIG. 4A in which FIG. 3 is a side view of a printed circuit board 100 according to one embodiment of the present disclosure, and FIG. 4A is a partial top view showing a zone M of FIG. 3 according to one embodiment of the present disclosure, and FIG. 4B is a partial top view showing the zone M of FIG. 3 according to another embodiment of the present disclosure.

The printed circuit board 100 includes a first substrate 110 and a plurality of first conductive contacts 120. The first substrate 110 can be, for example, a printed circuit board (PCB), a metal core printed circuit board (MCPCB) or a flexible printed circuit board (FPC).

The first conductive contacts 120 are arranged on a surface of the first substrate 110, and exchange information with an integrated circuit packaging component by adopting one or more wires in the printed circuit board 100. The first conductive contacts 120 can be metal contacts, and the material of the metal contacts can be copper, tin or nickel, etc. Also, the first conductive contacts 120 are not limited in shape, for example, can be a geometric shape such as a circular shape or a rectangular shape.

Each of the first conductive contacts 120 is formed with a soldering material layer 130 on a top surface 121 of the first conductive contacts 120. Each of the soldering material layers 130 is formed with a concave portion 140 thereon. Each of the concave portions 140 is not limited in profile, and does not need to shape exactly the same as the profile of the corresponding first conductive contact 120, for example, can be a geometric shape such as a circular shape or a rectangular shape. Each of the soldering material layers 130 is in a semi-solid or pasty state, and at least includes welding material (e.g., soldering paste etc.) and soldering flux.

In one alternative or option of the embodiment, each of the concave portions 140 is located on a central position (FIG. 4) of the profile (e.g., circular shape) of the corresponding soldering material layer 130. However, the disclosure is not limited to this specific embodiment.

In one alternative or option of the embodiment, each of the concave portions 140 penetrates through the corresponding soldering material layer 130, so that each of the concave portions 140 exposes the top surface 121 of the corresponding conductive contact 120 (FIG. 4A) through the corresponding soldering material layer 130. However, the disclosure is not limited to this specific embodiment, for example, referring to FIG. 4B, each of the concave portions 140 does not have to penetrate through the corresponding soldering material layer 130, so that a bottom surface of the concave portion 140 cannot expose the top surface 121 of the corresponding conductive contact 120 and still shields the top surface 121 of the corresponding conductive contact 120.

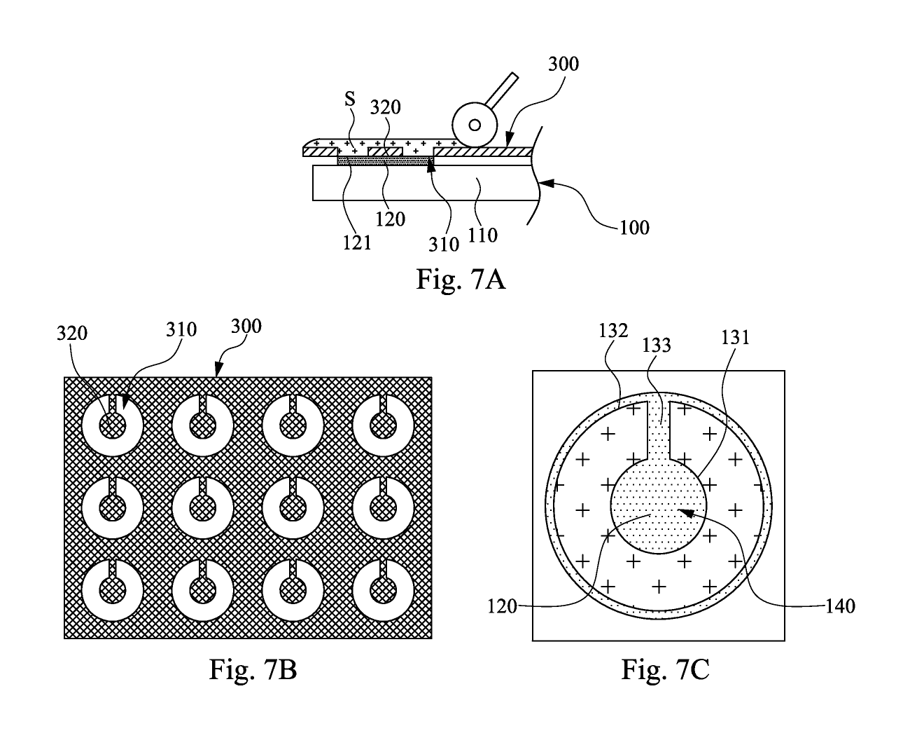

In one alternative or option of the embodiment, each of the concave portions 140 and the corresponding soldering material layer 130 are collaboratively presented as a concentric circle. In other words, an outer surface 132 of the soldering material layer 130 opposite to the concave portion 140 and an inner surface 131 of the soldering material layer 130 in the concave portion 140 all completely surround the concave portion 140. However, the disclosure is not limited to this specific embodiment. For example, the corresponding soldering material layer 130 can also be formed in a C type (FIG. 7C), a U type or a [symbol] type.

In other words, each of the soldering material layers 130 is provided with a slot 133. The slot 133 laterally connects both the outer surface 132 of the soldering material layer 130 and the inner surface 131 of the soldering material layer 130 in the concave portion 140. (FIG. 7C)

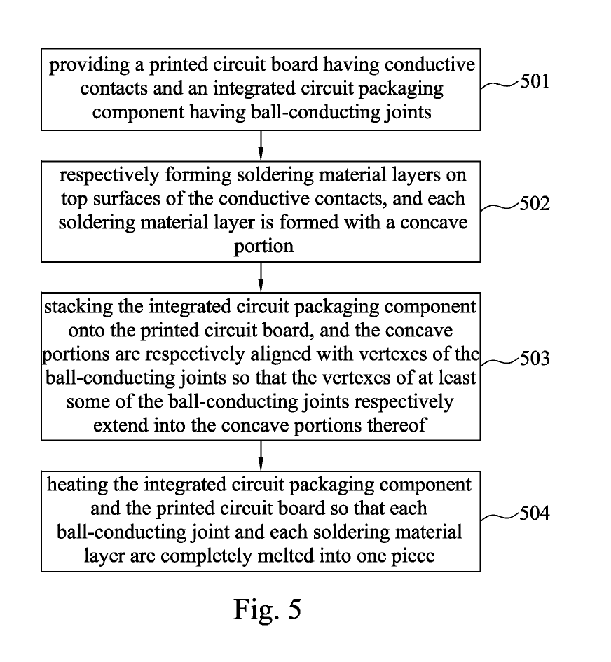

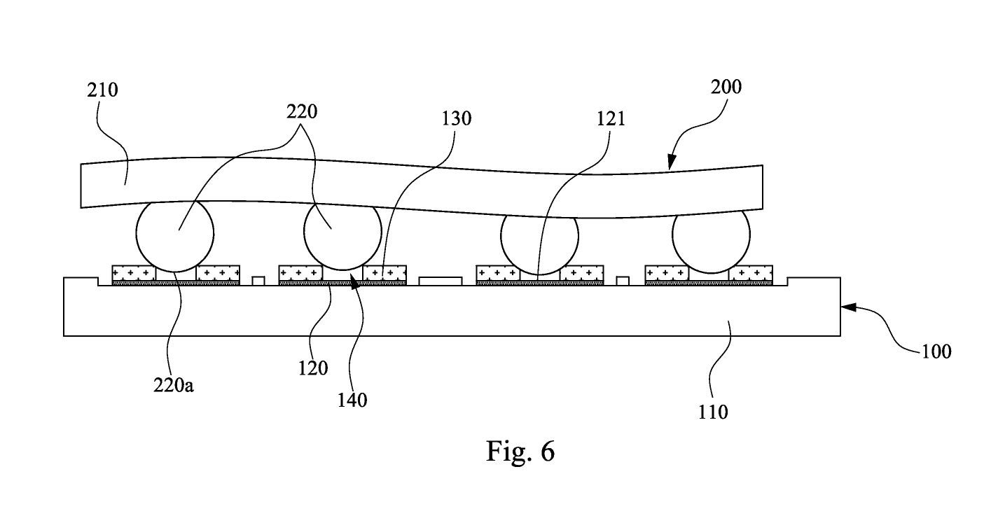

Reference is now made to FIG. 5 and FIG. 6. FIG. 5 is a flow chart showing a method of mounting an integrated circuit packaging component 200 on the printed circuit board 100 according to one embodiment of the present disclosure, and FIG. 6 is a schematic operational schematic view showing the integrated circuit packaging component 200 mounted on the printed circuit board 100 according to one embodiment of the present disclosure.

Referring to FIG. 5 and FIG. 6, the method of mounting an integrated circuit packaging component 200 on a printed circuit board 100 includes steps (501) to (504) as outlined below.

In Step (501), a printed circuit board 100 having a plurality of first conductive contacts 120 and an integrated circuit packaging component 200 having a plurality of ball-conducting joints 220 are provided. As shown in FIG. 6, the integrated circuit packaging component 200 includes a second substrate 210 and the ball-conducting joints 220. The ball-conducting joints 220 are respectively arranged and exposed on a surface of the second substrate 210, and the arrangement of the ball-conducting joints 220 is the same as and corresponding to the arrangement of the first conductive contacts 120. Each of the ball-conducting joints 220 is shown in a three-dimensional shape, and provided with a vertex 220a which the most protrusive point of the ball-conducting joints 220. When the integrated circuit packaging component 200 is warped in shape, minimum straight distances respectively defined between the printed circuit board 100 and all of the vertexes 220a of the ball-conducting joints 220 are not all the same.

In Step (502), a plurality of soldering material layers 130 are respectively formed on top surfaces 121 of the first conductive contacts 120, and each soldering material layer 130 is formed with a concave portion 140.

In Step (503), the integrated circuit packaging component 200 is stacked onto the printed circuit board 100, and the concave portions 140 are respectively aligned with vertexes 220a of the ball-conducting joints 220, so that the vertexes 220a of at least some of the ball-conducting joints 220 respectively extend into the concave portions 140 thereof.

In Step (504), both of the integrated circuit packaging component 200 and the printed circuit board 100 are heated, so that each ball-conducting joint 220 and each soldering material layer 130 are completely melted as one piece.

Therefore, referring to FIG. 6, since every vertexes 220a of all of the ball-conducting joints 220 thereof (or at least almost of the ball-conducting joints 220 thereof) respectively extend into the corresponding concave portions 140 thereof, one of the ball-conducting joints 220 (i.e., the leftmost ball-conducting joint 220) being farthest away from the printed circuit board 100 can still contact the corresponding soldering material layer 130 so as to allow the whole integrated circuit packaging component 200 to be closer to the printed circuit board 100.

After that, both of the integrated circuit packaging component 200 and the printed circuit board 100 are sent to a melting furnace. Although the integrated circuit packaging component 200 might still be warped in shape due to a high temperature condition of a melting furnace, yet, since the vertexes 220a of the ball-conducting joints 220 respectively extend into the corresponding concave portions 140 thereof, the ball-conducting joints 220 which are lifted due to warped still are highly possible to be completely melted as one piece with the corresponding soldering material layers 130, respectively.

Thus, in comparison with the conventional design of the soldering material layer without the concave portion, the present disclosure can reduce the quantity of the ball-conducting joints 220 which fails to be completely melted with the corresponding solder material layer 130 as one piece, so as to increase the possibility that all of the ball-conducting joints 220 are completely melted with the corresponding solder material layer 130 in one during the welding process.

To be noted, in the practice of the present disclosure, the ball-conducting joints 220 and the corresponding solder material layer 130 should be formed according to the type of the first conductive contacts 120. For example, when the area of the top surface 121 of one first conductive contact 120 is relatively enlarged, the corresponding ball-conducting joint 220 and the corresponding solder material layer 130 can be relatively enlarged, and the concave portion 140 corresponding to the ball-conducting joint 220 also can be relatively enlarged.

Furthermore, in one alternative or option of the embodiment, the capacity of the concave portion 140 can be enlarged to be greater than or equal to the volume of the ball-conducting joint 220, so that not only the vertex 220a of the ball-conducting joint 220, but also the whole ball-conducting joint 220 can be totally received inside the concave portion 140.

Reference is now made to FIG. 7A to FIG. 7C. FIGS. 7A and 7B are schematic operational views showing Step (502) of FIG. 5 according to one embodiment of the present disclosure, and FIG. 7C is a partial top view showing a solder material layer 130 formed on the printed circuit board 100 according to the embodiment of FIGS. 7A and 7B.

In Step (502), the soldering material layers 130 can be coated on the top surfaces 121 of the first conductive contacts 120 by printing.

Specifically, referring to FIG. 7A, the step (502) further comprises covering a printing stencil 300 on the printed circuit board 100 in which the printing stencil 300, in FIG. 7B, is provided with at least one opening 310 and one masking portion 320. The opening 310 is used to correspondingly exposes the top surface 121 of one of the first conductive contacts 120, and the masking portion 320 laterally extends into the opening from the printing stencil 300. In step (502), the step (502) further comprises distributing the soldering material S onto the printing stencil 300 and onto the printed circuit board 100 via the opening 310, such that the corresponding soldering material layer 130 and the corresponding concave portion 140 are complementarily formed on the top surface 121 of the first conductive contact 120 of the printed circuit board 100 (FIG. 7C).

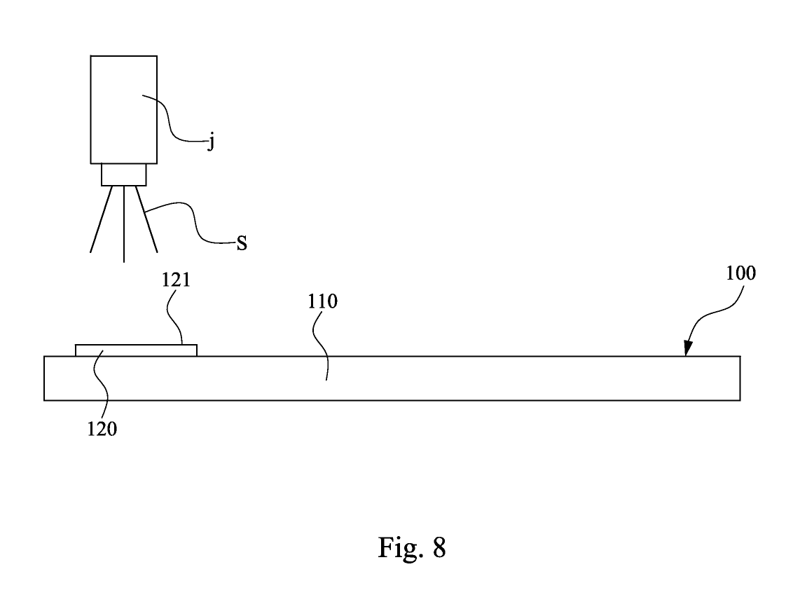

FIG. 8 is an operation schematic view showing step (502) of FIG. 5 according to another embodiment of the present disclosure. Referring to FIG. 8, in step (502), the soldering material layers 130 can be coated on the top surfaces 121 of the first conductive contacts 120 by spraying, that is, the solder material S can be sprayed on the top surface 121 of these first conductive contacts 120 such that the corresponding soldering material layer 130 and the corresponding concave portion 140 are directly formed on the top surface 121 of the first conductive contact 120 of the printed circuit board 100 without printing stencil.

Specifically, the soldering material layer 130 surrounding a concave portion 140 having no soldering material can be sprayed on the top surface 121 of the first conductive contact 120 of the printed circuit board 100 by a spraying machine J.

Although the present disclosure has been described with reference to the preferred embodiments thereof, it is apparent to those skilled in the art that a variety of modifications and changes may be made without departing from the scope of the present disclosure which is intended to be defined by the appended claims.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A printed circuit board for mounting an integrated circuit packaging component with ball-conducting joints, the printed circuit board comprising:
a substrate; and
a plurality of conductive contacts arranged on a surface of the substrate, each of the conductive contacts having a soldering material layer and a concave portion, wherein the soldering material layer is disposed on a top surface of the conductive contact, and the concave portion is disposed on the soldering material layer, and the concave portion is aligned with a vertex of one of the ball-conducting joints for receiving the vertex of the one of the ball conducting joints.

2. The printed circuit board according to claim 1, wherein each of the concave portions is located on a central position of the soldering material layer.

3. The printed circuit board according to claim 1, wherein each of the concave portions exposes a corresponding conductive contact through a corresponding soldering material layer.

4. The printed circuit board according to claim 1, wherein a bottom surface of each of the concave portions shields the corresponding conductive contact under the corresponding soldering material layer.

5. The printed circuit board according to claim 1, wherein an inner surface of each of the soldering material layers in a corresponding concave portion completely surrounds the corresponding concave portion.

6. The printed circuit board according to claim 1, wherein each of the soldering material layers has a slot, and the slot laterally connects an inner surface of the soldering material layer formed in the corresponding concave portion and an outer surface of the soldering material layer opposite to the inner surface thereof.

7. A method of mounting an integrated circuit packaging component on a printed circuit board, the method comprising:
(a) providing a printed circuit board having a plurality of conductive contacts, and an integrated circuit packaging component having a plurality of ball-conducting joints;
(b) respectively forming soldering material layers on top surfaces of the conductive contacts, wherein each of the soldering material layers is formed with a concave portion thereon;
(c) stacking the integrated circuit packaging component onto the printed circuit board, wherein the concave portions of the soldering material layers are respectively aligned with vertexes of the ball-conducting joints, such that the vertexes of at least some of the ball-conducting joints are respectively received in the corresponding concave portions; and
(d) heating the integrated circuit packaging component and the printed circuit board, such that each of the soldering material layers and the corresponding ball-conducting joint received in the concave portion are completely melted and connected as one piece.

8. The printed circuit board according to claim 7, wherein step (b) further comprises:
covering the printed circuit board with a printing stencil, wherein the printing stencil comprises a plurality of openings and a plurality of masking portions, and each of the openings correspondingly exposes the top surface of one of the conductive contacts, and each of the masking portions is laterally extended in one of the openings from the printing stencil; and
distributing soldering material onto the printing stencil and the printed circuit board via the openings, such that the soldering material layers and the concave portions are complementarily formed on the top surfaces of the conductive contacts of the printed circuit board.

9. The printed circuit board according to claim 7, wherein step (b) further comprises:
respectively spraying soldering material on the top surfaces of the conductive contacts of the printed circuit board, such that the soldering material layers and the concave portions are directly formed on the top surfaces of the conductive contacts of the printed circuit board.

10. The printed circuit board according to claim 7, wherein minimum straight line distances respectively defined between all of the vertexes of the ball-conducting joints and the printed circuit board are not all the same.
